(19) United States
(12) Patent Application Publication
(10) Pub. No.: US 2017/0053794 A1
(43) Pub. Date: Feb. 23, 2017

(54) AUTOMATIC CONTROL OF SPRAY BAR AND UNITS FOR CHEMICAL MECHANICAL POLISHING IN-SITU BRUSH CLEANING

(71) Applicant: GLOBALFOUNDRIES Inc., Grand Cayman (KY)

(72) Inventors: Hong Jin KIM, Ballston Spa, NY (US); Liqiao QIN, Albany, NY (US); Sumeet KASHYAP, Mechanicville, NY (US); Dinesh KOLI, Mechanicville, NY (US); Andrew KRANICK, Mechanicville, NY (US); Tae Hoon LEE, Clifton Park, NY (US); Hyucksoo YANG, Watervliet, NY (US); Jason MAZZOTTI, Saratoga Springs, NY (US)

(21) Appl. No.: 14/832,246

(22) Filed: Aug. 21, 2015

(51) Int. Cl. H01L 21/02; H01L 21/66; H01L 21/67; H01L 21/306

(52) U.S. Cl. CPC H01L 21/02043; H01L 21/30625; H01L 22/26; H01L 21/67051; H01L 21/67046; H01L 21/67253

(57) ABSTRACT

A method and apparatus are provided for automatically controlling the position of the spray bars and nozzles and the spray flow of a CMP in-situ cleaning module. Embodiments include fixing a wafer to a CMP cleaning module, the cleaning module having a first and a second group of spray bars and nozzles, the first and second groups of spray bars and nozzles being located proximate to opposite surfaces of the wafer; cleaning one or more of the surfaces of the wafer with a chemical spray forced through at least one of the groups of spray bars and nozzles; determining a measured profile of the one or more surfaces of the wafer; comparing the measured profile against a target profile; and adjusting automatically at least one of the first and second groups of spray bars and nozzles relative to the one or more surfaces of the wafer based on the comparison.

### TECHNICAL FIELD

The present disclosure relates to wafer processing systems, and more particularly to cleaning a wafer in a chemical mechanical polishing (CMP) in-situ cleaning module. The present disclosure is particularly applicable to the 14 nanometer (nm) technology node and beyond.

### BACKGROUND

A CMP polisher may have an in-situ cleaning module, which is composed of a brush scrubber with spray bars. Brush scrubber cleaning is an effective way to remove wafer surface particles by physical force. However, in addition to removing particles, the brush cleaning module may influence wafer uniformity at beyond 14 nm semiconductor manufacturing. As a result, chemical spray at the 14 nm technology node and beyond is more important than the brush scrubbers. However, depending on the spray bar position, particularly with respect to using hydrogen fluoride (HF), the cleaning chemical etch rate may vary considerably across the wafer. Known in-situ cleaning modules have a fixed spray bar position, which cannot be moved during the process. As a result, it is difficult to adjust the spray bar position with a high degree of accuracy and it is difficult to get tool to tool matching, which results in performance variation. For example, the etch amount may be greater at the center of a wafer than at the edges causing the thickness of the center of the wafer to be minimal and, therefore, creating a non-uniform wafer surface.

A need therefore exists for methodology and an apparatus enabling the automatic control of the position of the spray bars and nozzles and the spray flow of a CMP in-situ cleaning module.

### SUMMARY

An aspect of the present disclosure is a method for automatically controlling the position of the spray bars and nozzles and the spray flow of a CMP in-situ cleaning module.

Another aspect of the present disclosure is an apparatus including a CMP in-situ cleaning module having automatically adjustable spray bars and nozzles and spray flow.

Additional aspects and other features of the present disclosure will be set forth in the description which follows and in part will be apparent to those having ordinary skill in the art upon examination of the following or may be learned from the practice of the present disclosure. The advantages of the present disclosure may be realized and obtained as particularly pointed out in the appended claims.

According to the present disclosure, some technical effects may be achieved in part by a method including: fixing a wafer to a CMP cleaning module, the CMP cleaning module having a first and a second group of spray bars and nozzles, the first and second groups of spray bars and nozzles being located proximate to opposite surfaces of the wafer; cleaning one or more of the surfaces of the wafer with a chemical spray forced through at least one of the first and second groups of spray bars and nozzles; determining a measured a profile of the one or more surfaces of the wafer; comparing the measured profile against a target profile; and adjusting automatically at least one of the first and second groups of spray bars and nozzles relative to the one or more surfaces of the wafer based on the comparison.

Aspects of the present disclosure include cleaning one or more of the surfaces of the wafer with at least one of a first and a second scrub brush of the CMP cleaning module, the first and second scrub brushes located proximate to opposites surfaces of the wafer. Other aspects include measuring the profile by: measuring an etch amount and/or a removal amount across one or more of the surfaces of the wafer using a metrology system after brush cleaning. Further aspects include adjusting automatically the at least one of the first and second groups of spray bars and nozzles by: rotating the at least one of the first and second groups of spray bars and nozzles relative to the one or more surfaces of the wafer. Additional aspects include adjusting automatically the at least one of the first and second groups of spray bars and nozzles by: moving the at least one of the first and second groups of spray bars and nozzles parallel to the one or more surfaces of the wafer along a length of the at least one of the first and second groups spray bars and nozzles. Another aspect includes adjusting automatically the at least one of the first and second groups of spray bars and nozzles by: moving the at least one of the first and second groups of spray bars and nozzles parallel to the one or more surfaces of the wafer and perpendicular to a length of the at least one of the first and second groups spray bars and nozzles. Other aspects include automatically adjusting a flow of the chemical spray relative to the one or more surfaces of the wafer based on the comparison. Further aspects include adjusting the flow of the chemical spray by: changing a rate of the chemical spray being forced through the at least one of the first and second groups of spray bars and nozzles and/or closing one or more of the spray nozzles.

Another aspect of the present disclosure is an apparatus including: a CMP cleaning module, the CMP cleaning module having automatically adjustable first and second groups of spray bars and nozzles and a first and second scrub brush; and a wafer having first and second surfaces, the wafer vertically oriented with the first group of spray bars and nozzles and the first scrub brush being proximate to the first surface of the wafer and the second group of spray bars and nozzles and the second scrub brush being proximate to the second surface of the wafer.

Aspects of the apparatus include each of the first and second groups of spray bars and spray nozzles being formed of a first and second spray bar, each first and second spray bar having a plurality of spray nozzles formed along an edge. Other aspects include a control unit, wherein the control unit is configured to determine a measured profile of at least one of the first and second surfaces of the wafer. Further aspects include the first and second groups of spray bars being adjusted parallel to a length and/or a width of the first and second surfaces, respectively, of the wafer based on the measured profile. Additional aspects include the first and second groups of spray bars being rotated relative to the first and second surfaces, respectively, of the wafer based on the measured profile. Another aspect includes a flow through the first and second groups of spray bars and nozzles being adjusted relative to corresponding surfaces of the wafer based on the measured profile.

A further aspect of the present disclosure is an apparatus including: a processor; and a memory including computer program code for one or more programs, the memory and the computer program code configured to, with the processor, cause the apparatus to perform the following, fix a wafer vertically between a first and a second group of spray bars and nozzles and a first and a second scrub brush of a CMP cleaning module; clean one or more surfaces of the wafer with a chemical spray forced through one or more of the first and second groups of spray bars and nozzles; determine a measured profile of the one or more surfaces of the wafer; compare the measured profile against a target profile; and adjust automatically the one or more of the first and second groups of spray bars and nozzles relative to the one or more surfaces of the wafer based on the comparison.

Aspects of the apparatus include the apparatus being further caused, with respect to determining the measured profile, to: determine an etch amount and/or a removal amount across the one or more surfaces of the wafer. Other aspects include the apparatus being further caused, with respect to adjusting automatically the one or more of the first and second groups of spray bars and nozzles, to: rotate the one or more of the first and second groups of spray bars and nozzles relative to the one or more surfaces of the wafer. Further aspects include the apparatus being further caused, with respect to adjusting automatically the one or more of the first and second groups of spray bars and nozzles, to: move the one or more of the first and second groups of spray bars and nozzles along a length of the one or more of the first and second groups of spray bars and nozzles. Additional aspects include the apparatus being further caused, with respect to adjusting automatically one or more of the first and second groups of spray bars and nozzles, to: move the one or more of the first and second groups of spray bars and nozzles parallel to the one or more surfaces of the wafer and perpendicular to a length of the one or more of the first and second groups of spray bars and nozzles. Another aspect includes the apparatus being further caused, with respect to adjusting automatically the one or more of the first and second groups of spray bars and nozzles, to: adjust a flow of the chemical spray relative to the one or more surfaces wafer based on the comparison.

Additional aspects and technical effects of the present disclosure will become readily apparent to those skilled in the art from the following detailed description wherein embodiments of the present disclosure are described simply by way of illustration of the best mode contemplated to carry out the present disclosure. As will be realized, the present disclosure is capable of other and different embodiments, and its several details are capable of modifications in various obvious respects, all without departing from the present disclosure. Accordingly, the drawings and description are to be regarded as illustrative in nature, and not as restrictive.

### BRIEF DESCRIPTION OF THE DRAWINGS

The present disclosure is illustrated by way of example, and not by way of limitation, in the figures of the accompanying drawing and in which like reference numerals refer to similar elements and in which:

FIG. 1 illustrates an automatic control process flow for adjusting the position of the spray bars and nozzles and the spray flow of a CMP in-situ cleaning module, in accordance with an exemplary embodiment; and

FIG. 2 schematically illustrates a CMP cleaning apparatus based on the automatic control process flow, in accordance with an exemplary embodiment of the present disclosure.

### DETAILED DESCRIPTION

In the following description, for the purposes of explanation, numerous specific details are set forth in order to provide a thorough understanding of exemplary embodiments. It should be apparent, however, that exemplary embodiments may be practiced without these specific details or with an equivalent arrangement. In other instances, well-known structures and devices are shown in block diagram form in order to avoid unnecessarily obscuring exemplary embodiments. In addition, unless otherwise indicated, all numbers expressing quantities, ratios, and numerical properties of ingredients, reaction conditions, and so forth used in the specification and claims are to be understood as being modified in all instances by the term “about.”

The present disclosure addresses and solves the current problems of a difficulty with tool to tool matching, required manual adjustment of the position of the spray bars, tool contamination after adjustment, and a resulting lack of wafer surface uniformity attendant upon CMP in-situ cleaning of a wafer.

Methodology in accordance with embodiments of the present disclosure includes fixing a wafer to a CMP cleaning module, the CMP cleaning module having a first and a second group of spray bars and nozzles, the first and second groups of spray bars and nozzles being located proximate to opposite surfaces of the wafer. One or more of the surfaces of the wafer are cleaned with a chemical spray forced through at least one of the first and second groups of spray bars and nozzles. A profile of the one or more surfaces of the wafer is measured and the measured profile is compared against a target profile. At least one of the first and second groups of spray bars and nozzles is automatically adjusted relative to the one or more surfaces of the wafer based on the comparison.

Still other aspects, features, and technical effects will be readily apparent to those skilled in this art from the following detailed description, wherein preferred embodiments are shown and described, simply by way of illustration of the best mode contemplated. The disclosure is capable of other and different embodiments, and its several details are capable of modifications in various obvious respects. Accordingly, the drawings and description are to be regarded as illustrative in nature, and not as restrictive.

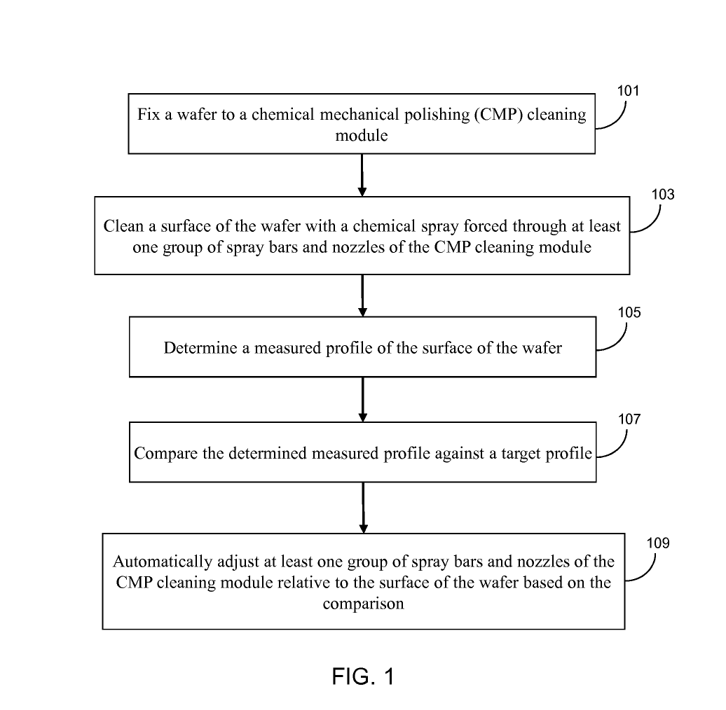

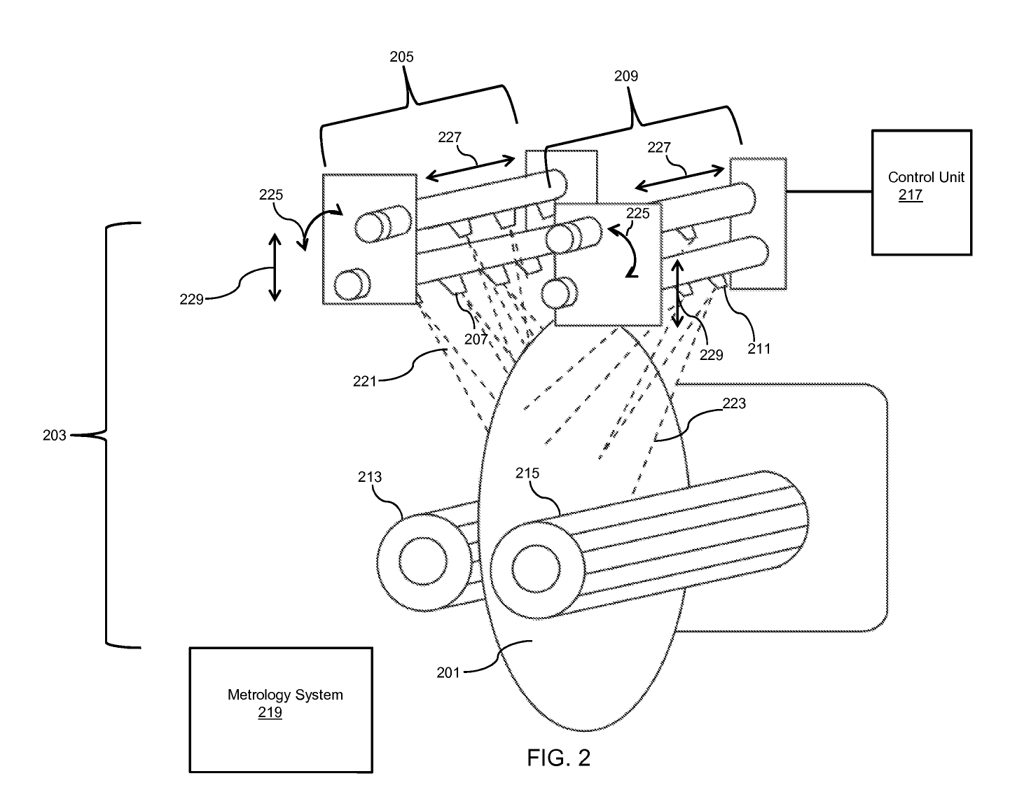

FIG. 1 illustrates an automatic control process flow for adjusting the position of the spray bars and nozzles and the spray flow of a CMP in-situ cleaning module, in accordance with an exemplary embodiment, and FIG. 2 schematically illustrates a CMP cleaning apparatus based on the automatic control process flow, in accordance with an exemplary embodiment of the present disclosure. In step 101, a wafer, e.g., a 14 nm wafer, is fixed to a CMP cleaning module that has two groups of spray bars and nozzles, the two groups of spray bars being located proximate to opposite surfaces of the wafer. For example, the wafer 201 of FIG. 2 may be fixed to the CMP cleaning module 203 that has a group of spray bars 205 with nozzles 207 and a group of spray bars 209 with nozzles 211 located proximate to opposite surfaces of the wafer 201. As depicted in FIG. 2, the nozzles 207 and 211 are formed along an edge of the spray bars 205 and 207, respectively. The CMP cleaning module 203 also includes scrub brushes 213 and 215 located proximate to opposite surfaces of the wafer 201. Further, the CMP cleaning module 203 also includes a control unit 217, e.g., a processor and a memory including computer program code for one or more programs, for automatically adjusting the group of spray bars 205 and nozzles 207 and/or the group of spray bars 209 and nozzles 211 and for determining, e.g., receiving, a measured profile of one or more surfaces of the wafer 201 from an on-board or standalone metrology system 219.

In step 103, one or more of the surfaces of the wafer are cleaned with a chemical spray forced through at least one group of the spray bars and nozzles and with scrub brushes. For example, the control unit 217 may cause the chemical spray 221 to be forced through the group of spray bars 205 and nozzles 207 onto a surface of the wafer 201 and/or cause the chemical spray 223 to be forced through the group of spray bars 209 and nozzles 211 onto the other surface of the wafer 201. The chemical spray 221 may, for example, be formed of a mixture of chlorine sodium hydrogen fluoride or a mixture of HF. In addition, the control unit 217 may cause, for example, the scrub brushes 213 and 215 to rotate and to clean one or more surfaces of the wafer 201.

In step 105, after cleaning the wafer 201 with brushes 213 and 215, a profile of the one or more surfaces of the wafer upon which the spray has been directed is measured by an on-board or standalone metrology system. For example, the wafer 201 is removed from the CMP cleaning module 203, measured using the metrology system 219, and then the wafer 201 or a new wafer is fixed back into the CMP module 203. The metrology system 219 may measure an etch amount, e.g., how much material is removed, and/or a removal amount, e.g., the thickness of the remaining wafer. The etch amount may depend on the chemical spray mixture and the removal amount may depend on the amount of elapsed cleaning time.

In step 107, the measured profile is compared against a target profile, e.g., a target profile based on a particular technology or device. In step 109, at least one group of spay bars and nozzles is automatically adjusted relative to the one or more surfaces of the wafer based on the comparison. For example, the control unit 217 can cause the spray bars 205 and nozzles 207 and/or the spray bars 209 and nozzles 211 to rotate relative to a surface of the wafer 201, as depicted by the arrows 225. The control unit 217 can also cause the spray bars 205 and nozzles 207 and/or the spray bars 209 and nozzles 211 to move parallel to the one or more surfaces of the wafer 201 and along a length of the spray bars 205 and 209, i.e., in a horizontal direction, as depicted by the arrows 227. In addition, or alternatively, the control unit 217 can also cause the spray bars 205 and nozzles 207 and/or the spray bars 209 and nozzles 211 to move parallel to a surface of the wafer 201 and perpendicular to a length of the spray bars 205 and 209, i.e., in a vertical direction, as depicted by the arrows 229. Further, the control unit 217 can cause an adjustment of the flow of the chemical sprays 221 and/or 223 by changing a rate of the chemical spray being forced through the spray bars 205 and nozzles 207 and/or the spray bars 209 and nozzles 211 and/or by closing one or more of the spray nozzles 207 and 211.

The embodiments of the present disclosure can achieve several technical effects including maximizing cleaning efficiency as well as wafer surface uniformity. The disclosed CMP cleaning module can also be applicable to brush cleaning automatic process control (iAPC) implementation. Embodiments of the present disclosure enjoy utility in various industrial applications as, for example, microprocessors, smart phones, mobile phones, cellular handsets, set-top boxes, DVD recorders and players, automotive navigation, printers and peripherals, networking and telecom equipment, gaming systems, and digital cameras. The present disclosure therefore enjoys industrial application for the 14 nm technology node and beyond

In the preceding description, the present disclosure is described with reference to specifically exemplary embodiments thereof. It will, however, be evident that various modifications and changes may be made thereto without departing from the broader spirit and scope of the present disclosure, as set forth in the claims. The specification and drawings are, accordingly, to be regarded as illustrative and not as restrictive. It is understood that the present disclosure is capable of using various other combinations and embodiments and is capable of any changes or modifications within the scope of the inventive concept as expressed herein.

What is claimed is:

1. A method comprising:
fixing a wafer to a chemical mechanical polishing (CMP) cleaning module, the CMP cleaning module having a first and a second group of spray bars and nozzles, the first and second groups of spray bars and nozzles being located proximate to opposite surfaces of the wafer;
cleaning one or more of the surfaces of the wafer with a chemical spray forced through at least one of the first and second groups of spray bars and nozzles;
determining a measured profile of the one or more surfaces of the wafer;
comparing the measured profile against a target profile; and
adjusting automatically at least one of the first and second groups of spray bars and nozzles relative to the one or more surfaces of the wafer based on the comparison.

2. The method according to claim 1, further comprising cleaning one or more of the surfaces of the wafer with at least one of a first and a second scrub brush of the CMP cleaning module, the first and second scrub brushes located proximate to opposite surfaces of the wafer.

3. The method according to claim 1, further comprising measuring the profile by:
measuring an etch amount and/or a removal amount across one or more of the surfaces of the wafer using a metrology system after brushing cleaning.

4. The method according to claim 1, comprising adjusting automatically the at least one of the first and second groups of spray bars and nozzles by:
rotating the at least one of the first and second groups of spray bars and nozzles relative to the one or more surfaces of the wafer.

5. The method according to claim 1, comprising adjusting automatically the at least one of the first and second groups of spray bars and nozzles by:
moving the at least one of the first and second groups of spray bars and nozzles parallel to the one or more surfaces of the wafer along a length of the at least one of the first and second groups spray bars and nozzles.

6. The method according to claim 1, comprising adjusting automatically the at least one of the first and second groups of spray bars and nozzles by:
moving the at least one of the first and second groups of spray bars and nozzles parallel to the one or more surfaces of the wafer and perpendicular to a length of the at least one of the first and second groups spray bars and nozzles.

7. The method according to claim 1, further comprising automatically adjusting a flow of the chemical spray relative to the one or more surfaces of the wafer based on the comparison.

8. The method according to claim 7, comprising adjusting the flow of the chemical spray by:
changing a rate of the chemical spray being forced through the at least one of the first and second groups of spray bars and nozzles and/or closing one or more of the spray nozzles.

9. An apparatus comprising:
a chemical mechanical polishing (CMP) cleaning module, the CMP cleaning module having automatically adjustable first and second groups of spray bars and nozzles and a first and second scrub brush; and
a wafer having first and second surfaces, the wafer vertically oriented with the first group of spray bars and nozzles and the first scrub brush being proximate to the first surface of the wafer and the second group of spray bars and nozzles and the second scrub brush being proximate to the second surface of the wafer.

10. The apparatus according to claim 9, wherein each of the first and second groups of spray bars and spray nozzles is formed of a first and second spray bar, each first and second spray bar having a plurality of spray nozzles formed along an edge.

11. The apparatus according to claim 9, further comprising a control unit, wherein the control unit is configured to determine a measured profile of at least one of the first and second surfaces of the wafer.

12. The apparatus according to claim 11, wherein the first and second groups of spray bars may be adjusted parallel to a length and/or a width of the first and second surfaces, respectively, of the wafer based on the measured profile.

13. The apparatus according to claim 11, wherein the first and second groups of spray bars may be rotated relative to the first and second surfaces, respectively, of the wafer based on the measured profile.

14. The apparatus according to claim 11, wherein a flow through the first and second groups of spray bars and nozzles may be adjusted relative to corresponding surfaces of the wafer based on the measured profile.

15. An apparatus comprising:
a processor; and
a memory including computer program code for one or more programs, the memory and the computer program code configured to, with the processor, cause the apparatus to perform the following,
fix a wafer vertically between a first and a second group of spray bars and nozzles and a first and a second scrub brush of a chemical mechanical polishing (CMP) cleaning module;
clean one or more surfaces of the wafer with a chemical spray forced through one or more of the first and second groups of spray bars and nozzles;
determine a measured profile of the one or more surfaces of the wafer;
compare the measured profile against a target profile; and
adjust automatically the one or more of the first and second groups of spray bars and nozzles relative to the one or more surfaces of the wafer based on the comparison.

16. The apparatus according to claim 15, wherein the apparatus is further caused, with respect to determining the measured profile, to:
determine an etch amount and/or a removal amount across the one or more surfaces of the wafer.

17. The apparatus according to claim 15, wherein the apparatus is further caused, with respect to adjusting automatically the one or more of the first and second groups of spray bars and nozzles, to:
rotate the one or more of the first and second groups of spray bars and nozzles relative to the one or more surfaces of the wafer.

18. The apparatus according to claim 15, wherein the apparatus is further caused, with respect to adjusting automatically the one or more of the first and second groups of spray bars and nozzles, to:
move the one or more of the first and second groups of spray bars and nozzles along a length of the one or more of the first and second groups of spray bars and nozzles.

19. The apparatus according to claim 15, wherein the apparatus is further caused, with respect to adjusting automatically one or more of the first and second groups of spray bars and nozzles, to:
move the one or more of the first and second groups of spray bars and nozzles parallel to the one or more surfaces of the wafer and perpendicular to a length of the one or more of the first and second groups of spray bars and nozzles.

20. The apparatus according to claim 15, wherein the apparatus is further caused, with respect to adjusting automatically the one or more of the first and second groups of spray bars and nozzles, to:
adjust a flow of the chemical spray relative to the one or more surfaces wafer based on the comparison.
